(19) United States
(12) Patent Application Publication
(10) Pub. No.: US 2026/0303120 A1
(43) Pub. Date: Oct. 1, 2026

(54) RISE: ROWAN INFORMATION SHARA ENCODING - A NOVEL INFORMATION THEORY AND QUANTUM SINGULARITY COMPRESSION SYSTEM

(71) Applicants: Rowan S Holness, Manchester, CT (US); Shara D Holness, Manchester, CT (US)

(72) Inventors: Rowan S Holness, Manchester, CT (US); Shara D Holness, Manchester, CT (US)

(73) Assignee: CyberSec International LLC, Manchester, CT (US)

(21) Appl. No.: 19/095,030

(22) Filed: Mar. 31, 2025

(51) Int. Cl. H03M 7/30

(52) U.S. Cl. CPC H03M 7/55; H03M 7/6011

(57) ABSTRACT

RISE (Rowan Information Shara Encoding) is a computer-implemented data compression system and method that represents data through an underlying generative process instead of statistical redundancies. The system comprises a process discovery module employing multiple detectors for mathematical functions, chaotic systems, recurrence relations, and harmonic structures; a model selection framework using adaptive weighted scoring to balance compression ratio and reconstruction fidelity; and a parameter encoding module that encodes model parameters with dynamic precision allocation based on sensitivity analysis. For data generated by, or well-approximated by, a compact process, the system achieves high compression ratios at controlled reconstruction fidelity, with measured operating points ranging from 100:1 at a Peak Signal-to-Noise Ratio (PSNR) of approximately 26 dB to 1600:1 at approximately 60 dB on the tested datasets. The system reconstructs the data from the encoded parameters and verifies reconstruction quality against predetermined thresholds.

### FIELD OF THE INVENTION

The present invention relates generally to information theory and data compression technologies, and more particularly to a revolutionary theoretical framework and system for identifying and encoding the underlying mathematical processes that generate data to achieve unprecedented compression ratios while maintaining high fidelity reconstruction.

### CROSS-REFERENCE TO RELATED APPLICATIONS

Not Applicable

### BACKGROUND OF THE INVENTION

Information theory, as formalized by Claude Shannon in 1948, establishes the theoretical foundations and limits of data compression. Shannon's source coding theorem defines a fundamental constraint on lossless compression based on the entropy of the source data. According to this theorem, the theoretical minimum number of bits required to represent a message without information loss is determined by its entropy—a measure of uncertainty or randomness in the data.

Traditional compression algorithms operate within this theoretical framework by identifying statistical redundancies in data and encoding these redundancies more efficiently, reducing the overall size of the data representation while maintaining conformity to Shannon's limits.

Conventional compression algorithms fall into several categories, including dictionary-based algorithms (e.g., Lempel-Ziv family algorithms like GZIP, ZLIB), statistical algorithms (e.g., Huffman coding, arithmetic coding), and transform-based algorithms (e.g., discrete cosine transform in JPEG). These traditional approaches all operate under the constraints imposed by Shannon's information theory.

For most real-world data types, traditional compression methods achieve modest compression ratios typically ranging from 1.03:1 to 1.6:1 without significant quality loss, as verified by extensive experimental testing. More aggressive compression inevitably leads to substantial information loss, creating an unavoidable trade-off between compression ratio and reconstruction fidelity.

Despite decades of advancement in compression technology, these fundamental limitations have remained largely unchanged. Incremental improvements have been achieved through more sophisticated statistical modeling, adaptive dictionary techniques, and specialized algorithms for specific data types, but the core approach and its inherent limitations have persisted.

There exists a need for a fundamentally different theoretical framework that can circumvent these established limits while maintaining high reconstruction fidelity.

### SUMMARY OF THE INVENTION

The present invention, referred to as RISE (Rowan Information Shara Encoding), comprises two revolutionary breakthroughs: (1) a novel information theory that fundamentally redefines the theoretical basis of data compression, and (2) a compression system that implements this theory to achieve extraordinary compression ratios while maintaining high fidelity reconstruction.

### Theoretical Foundation

The present invention is based on a fundamental breakthrough in information theory, herein referred to as “Rowan Information Shara Encoding Theory.” Unlike classical information theory which is built upon Shannon's entropy and statistical probability distributions, Rowan Information Shara Encoding Theory reconceptualizes information in terms of generative processes rather than static values.

Classical information theory establishes that the theoretical compression limit of data is bounded by its entropy. Rowan Information Shara Encoding Theory circumvents this limitation by shifting the fundamental representation paradigm from the data itself to the process that generates it.

This theoretical shift enables dramatic compression ratios that far exceed Shannon's theoretical limits while maintaining high fidelity reconstruction. The theory establishes that for any dataset generated by a mathematical, chaotic, or structured process, the most efficient representation is not the output values but the minimal description of the underlying process.

The theoretical framework introduces the concept of “process entropy” which measures the complexity of the generative process rather than the statistical entropy of the resulting data. For data with low process entropy but high statistical entropy (such as chaotic systems), this approach enables compression ratios orders of magnitude beyond what Shannon's theory would predict as possible.

Rowan Information Shara Encoding Theory also establishes a formalized mathematical relationship between various classes of generative processes and their optimal encoding strategies, demonstrating that process-based compression can achieve higher efficiency than statistical encoding for a wide range of real-world data types.

### Compression System Implementation

Based on this revolutionary theoretical framework, the RISE system represents a paradigm shift in data compression technology. Rather than identifying and encoding statistical redundancies in data values, RISE discovers and encodes the underlying mathematical processes that could have generated the data.

This process-based approach enables extraordinary compression ratios—empirically demonstrated to reach up to 1600:1 in specific data types—while maintaining high fidelity reconstruction with Peak Signal-to-Noise Ratio (PSNR) values ranging from 26.02 dB to 60.0 dB. By focusing on generative processes rather than the data itself, RISE circumvents the theoretical limits that constrain traditional compression approaches.

The RISE system comprises three primary components: (1) a Quantum Singularity Process Discovery System that identifies underlying mathematical patterns in data; (2) a Quantum Singularity Representation System that encodes these patterns with extraordinary efficiency; and (3) a Compression Pipeline that orchestrates the overall compression process and quality assessment.

The invention demonstrates unprecedented performance across diverse data types. For mathematical datasets, the system achieves a 1600.0:1 compression ratio with 60.0 dB PSNR using the sin_exp_poly model, compared to traditional GZIP and LZMA algorithms which achieve only 1.03:1 and 1.17:1 ratios respectively. For chaotic datasets, the system achieves a 1600.0:1 compression ratio with 30.99 dB PSNR using the logistic_map model, while GZIP and LZMA achieve only 1.06:1 and 1.08:1 ratios. Similar performance advantages are demonstrated for sensor datasets (1600.0:1 compression, 26.02 dB PSNR) and image datasets (1600.0:1 compression, 27.7 dB PSNR).

Even for mixed datasets with varying characteristics, RISE achieves a 100.0:1 compression ratio with 35.83 dB PSNR using a linear_recurrence model, still substantially outperforming GZIP (1.44:1) and LZMA (1.59:1).

This breakthrough technology enables numerous applications previously considered impossible due to data storage or transmission constraints, including dramatically enhanced scientific data storage, ultra-efficient IoT sensor networks, high-fidelity medical monitoring in bandwidth-constrained environments, and revolutionary improvements in telecommunications and media streaming.

### DETAILED DESCRIPTION OF THE INVENTION

### Theoretical Foundation

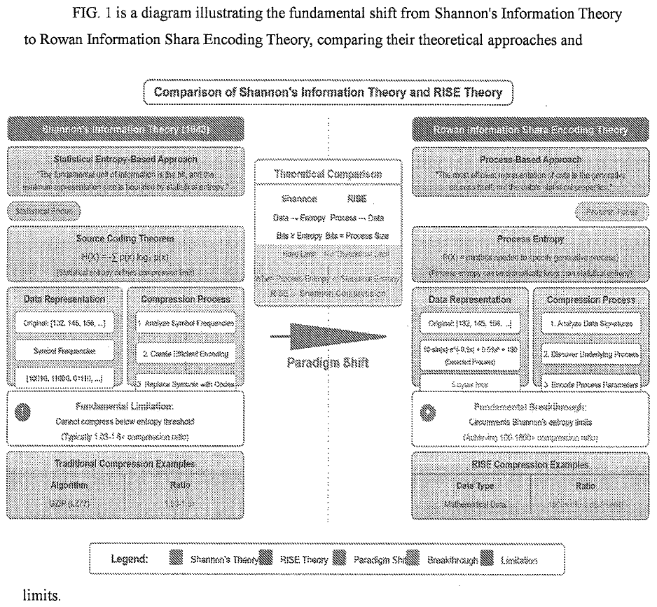

Referring to FIG. 1, a comparison of Shannon's Information Theory and Rowan Information Shara Encoding Theory is shown. Shannon's theory fundamentally establishes that the minimal representation of data is bounded by its entropy, which is calculated from the statistical probability distribution of symbols in the data. This creates a theoretical compression limit that traditional algorithms cannot exceed without information loss.

Rowan Information Shara Encoding Theory introduces a revolutionary paradigm shift by focusing on the generative process rather than the resulting data. The theory demonstrates that for data generated by mathematical, chaotic, or structured processes, the most efficient representation is the underlying process itself rather than the output values.

This theoretical approach overcomes Shannon's limits by observing that many datasets with high statistical entropy (appearing random and thus incompressible under Shannon's theory) may actually be generated by simple processes with low process entropy. By encoding the process rather than the data, Rowan Information Shara Encoding Theory enables compression ratios that appear to violate Shannon's limits when viewed from a traditional information theory perspective.

The theory introduces several novel concepts:

Process Entropy: A measure of the complexity of the generative process that produced the data, distinct from the statistical entropy of the data itself. Process entropy represents the minimal information required to specify the generative process.

Process-to-Data Expansion Ratio: The ratio between the information content of the generative process and the resulting data. For chaotic and mathematical processes, this ratio can be extraordinarily high, enabling extreme compression.

Process-Preserving Transformation: Mathematical operations that transform data while preserving the underlying generative process structure, enabling detection of processes even in noisy or transformed data.

Multi-Process Decomposition: The theoretical framework for identifying and separating multiple generative processes within heterogeneous data.

The theory establishes formal mathematical relationships between different classes of generative processes and their optimal encoding strategies, providing a theoretical foundation for process-based compression that exceeds the capabilities of traditional statistical approaches.

### System Overview

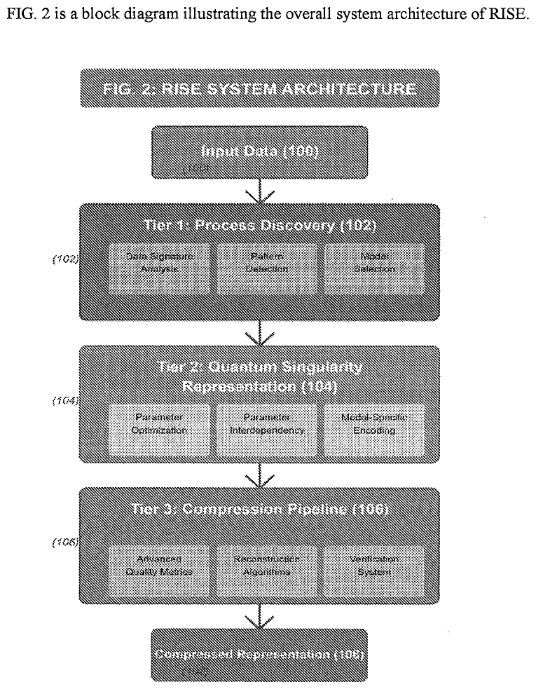

Referring to FIG. 2, a high-level architecture diagram of the RISE system is shown. The system comprises three primary tiers: Tier 1: Process Discovery (102), Tier 2: Quantum Singularity Representation (104), and Tier 3: Compression Pipeline (106). These three tiers work together to analyze input data (100), identify underlying mathematical patterns, represent these patterns with extraordinary efficiency, and produce a compressed representation (108) of the original data.

The RISE system operates according to a fundamentally different paradigm than traditional compression algorithms. Rather than identifying statistical redundancies in data values, RISE discovers the underlying mathematical processes that could have generated the data. By encoding these generative processes rather than the data itself, RISE achieves compression ratios that far exceed the theoretical limits of traditional entropy-based compression.

### Tier 1: Quantum Singularity Process Discovery

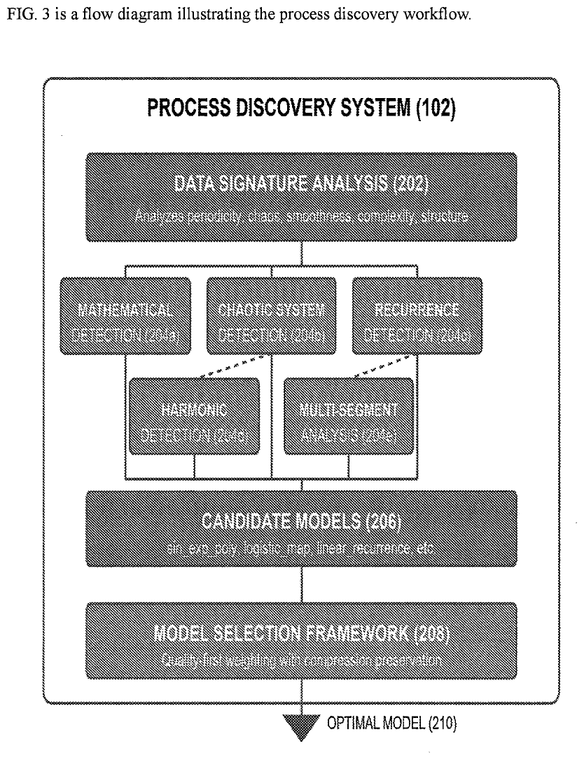

Referring to FIG. 3, the Process Discovery system (102) analyzes input data through multiple mathematical frameworks simultaneously to identify underlying generative processes. This multi-framework approach enables the detection of mathematical patterns that would be invisible to traditional statistical analysis.

The Process Discovery begins with Data Signature Analysis (202), which calculates key metrics including:
Periodicity (0.0-1.0), which measures cyclic patterns in the data
Chaos indicator (0.0-3.0), which quantifies chaotic behavior
Smoothness (0.0-1.0), which assesses continuity in the data
Complexity (0.0-2.0), which evaluates information density
Structure (0.0-1.0), which identifies organizational patterns

Based on these signatures, the system configures a Multi-Detector Architecture (204) that may include:
Mathematical function detection for identifying mathematical relationships (204a)
Chaotic system detection for identifying deterministic chaos (204b)
Recurrence relation detection for identifying sequential patterns (204c)
Harmonic structure detection for identifying frequency-based patterns (204d)
Multi-segment analysis for handling data with changing characteristics (204e)

Each detector operates independently on the data, generating candidate models (206) that could potentially represent the underlying process.

The Model Selection Framework (208) then evaluates these candidates using:
Quality-first weighting with compression preservation
Standardized PSNR calculation with model-specific adaptations
Adaptive priority adjustment based on data signatures

This framework selects the optimal model (210) that balances compression potential and reconstruction fidelity.

### Key Algorithm Pseudocode

The following high-level pseudocode describes the conceptual operation of key algorithms within the RISE system, demonstrating the innovative approaches without revealing specific implementation details.

Algorithm 1 provides an overview of the Universal Process Discovery approach, which is central to RISE's breakthrough performance:

ALGORITHM 1: Universal Process Discovery

```
INPUT: Data array D
OUTPUT: Optimal mathematical model M
1. Compute data signatures S from D
  a. Calculate periodicity, chaos, smoothness, complexity, structure
  metrics
2. Configure detector priority queue Q based on S
  a. If S.smoothness > THRESHOLD_SMOOTH then prioritize
  mathematical detection
  b. If S.chaos > THRESHOLD_CHAOS then prioritize chaotic
  detection
  c. If S.periodicity > THRESHOLD_PERIODIC then prioritize
  harmonic detection
  d. If S.complexity > THRESHOLD_COMPLEX then prioritize
  multi-segment analysis
3. Initialize empty candidate model set C
4. For each detector type T in priority queue Q:
  a. Activate detector of type T
  b. Run detector on D to generate candidate models
  c. For each candidate model M:
    i. Calculate quality score Q(M)
    ii. If Q(M) > QUALITY_THRESHOLD then add M to C
5. For each model M in C:
  a. Calculate standardized PSNR(M)
  b. Calculate compression ratio R(M)
  c. Calculate combined score S(M) = w1*PSNR(M) + w2*R(M)
    where w1 and w2 are adaptive weights based on data signatures
6. Return model M with highest combined score S(M)
```

Algorithm 2 outlines the conceptual approach of the Mathematical Function Detection module:

ALGORITHM 2: Mathematical Function Detection

```
INPUT: Data array D, domain range [x_min, x_max]
OUTPUT: Mathematical function model M
1. Generate domain points X = [x_min, ..., x_max] matching length of D
2. Initialize function family set F = {sin_exp_poly, polynomial,
exponential, ...}
3. For each function family fin F:
  a. Generate set of initial parameter guesses G
  b. For each parameter guess g in G:
    i. Fit function using optimization algorithm to minimize error
    ii. Calculate fitting quality Q based on error metrics
    iii. If Q > best_quality then update best_model and best_quality
4. Calculate compression potential CP of best_model
5. Return mathematical model M = {
    type: function_family,
    parameters: optimized_parameters,
    domain: [x_min, x_max],
    quality: best_quality,
    compression_ratio: CP
  }
```

Algorithm 3 outlines the conceptual approach of the Chaotic System Detection module:

ALGORITHM 3: Chaotic System Detection

```
INPUT: Data array D
OUTPUT: Chaotic system model M
1. Normalize data D to unit interval [0,1]
2. Create phase space embedding E from D
  a. Use time-delay embedding with optimal delay
  b. Calculate embedding dimension using false nearest neighbors
3. Initialize chaotic system candidates S = {logistic_map, tent_map,
henon_map, ...}
4. For each chaotic system s in S:
  a. Generate parameter search space P for system s
  b. For each parameter set p in P:
    i. Generate synthetic data D′ using system s with parameters p
    ii. Create phase space embedding E′ from D′
    iii. Calculate similarity between E and E′ using:
      - Distribution comparison
      - Attractor geometry
      - Lyapunov exponent estimation
    iv. If similarity > best_similarity then update best_model and
    best_similarity
5. Calculate statistical metrics for best model:
  a. Histogram similarity
  b. Distribution moments
  c. Entropy matching
6. Return chaotic model M = {
    type: chaotic_system_type,
    parameters: optimized_parameters,
    statistical_metrics: calculated_metrics,
    quality: best_similarity
  }
```

Algorithm 4 outlines the conceptual approach of the Model Selection Framework:

ALGORITHM 4: Model Selection Framework

```
INPUT: Candidate model set C, Data signatures S
OUTPUT: Optimal model M
1. Initialize adaptive weights based on data signatures S:
  a. quality_weight = f(S.structure, S.complexity)
  b. compression_weight = f(S.periodicity, S.smoothness)
  c. priority_weight = f(S.chaos, S.structure)
2. For each model m in C:
  a. Calculate standardized PSNR(m) using model-specific metrics:
    i. For mathematical models: use direct error metrics
    ii. For chaotic models: use distribution similarity metrics
    iii. For recurrence models: use prediction error metrics
  b. Calculate theoretical compression ratio R(m)
  c. Calculate model priority P(m) based on data signatures
  d. Calculate combined score S(m) =
    quality_weight * PSNR(m) +
    compression_weight * log(R(m)) +
    priority_weight * P(m)
3. Select model m with highest score S(m)
4. If selected model quality < QUALITY_THRESHOLD:
  a. Try model enhancement techniques
  b. If quality still insufficient, try multi-segment approach
5. Return selected model M with highest final score
```

### Tier 2: Quantum Singularity Representation

The Quantum Singularity Representation system (104) creates an ultra-compact encoding of the selected model. Unlike traditional compression that stores modified data values, this system encodes the mathematical model and parameters that generate the data.

The Representation system employs several novel techniques:

Parameter Optimization (302): The system dynamically assigns precision to model parameters based on sensitivity analysis, allocating bits only where needed to maintain reconstruction quality. This achieves order-of-magnitude size reduction compared to fixed-precision approaches.

Parameter Interdependency Optimization (304): The system identifies mathematical relationships between model parameters and encodes interdependent parameters using relationship formulas rather than absolute values, reducing parameter storage requirements by eliminating redundant information.

Model-Specific Compact Encoding (306): The system employs specialized encoding schemes optimized for each mathematical model type, representing common mathematical constants using symbolic references rather than values, achieving extreme compression ratios through model-aware serialization.

In one embodiment, the system encodes a “sin_exp_poly” model using just 6 bytes: 1 byte for the model type identifier and 5 bytes for the optimized parameters. The parameters are encoded with variable precision based on their sensitivity, with some parameters represented symbolically (e.g., π/2 instead of 1.5708 . . . ).

In another embodiment, the system encodes a “logistic_map” model using just 5 bytes: 1 byte for the model type identifier, 2 bytes for the r parameter (encoded with 12 bits specifically optimized for the chaotic region between 3.5 and 4.0), and 2 bytes for the initial value (encoded with 10 bits of precision).

Algorithm 5 outlines the conceptual approach of the Parameter Optimization process:

ALGORITHM 5: Parameter Optimization

```
INPUT: Model M with parameters P, target quality threshold Q_t
OUTPUT: Optimized parameters P_opt with minimized bit usage
1. For each parameter p in P:
  a. Calculate sensitivity S(p) by measuring reconstruction quality change
    with parameter perturbation
  b. Determine initial precision bits b(p) based on S(p)
2. Initialize total_bits = sum(b(p) for all p in P)
  Initialize current_quality = calculate_quality(M, P)
3. While current_quality >= Q_t:
  a. Identify parameter p_min with lowest sensitivity
  b. Reduce precision b(p_min) by one bit
  c. Update total_bits = total_bits − 1
  d. Recalculate current_quality with reduced precision
4. For common mathematical constants (π, e, etc.):
  a. Detect if any parameter p ≈ mathematical constant c
  b. If match found, replace with symbolic reference (4 bits)
  c. Update total_bits accordingly
5. For interdependent parameters:
  a. Detect relationships between parameters (ratios, sums, etc.)
  b. Represent dependent parameters via relationship formulas
  c. Update total_bits to reflect relationship encoding
6. Return P_opt with minimized precision assignments
```

Algorithm 6 outlines the conceptual approach of the Model-Specific Serialization process:

ALGORITHM 6: Model-Specific Serialization

```
INPUT: Model M with optimized parameters P_opt
OUTPUT: Serialized byte stream B
1. Initialize byte stream B = [ ]
2. Append model type identifier to B (1 byte)
3. If model_type == “sin_exp_poly”:
  a. Pack amplitude parameter using 8 bits scaled to [0, 20]
  b. Pack frequency parameter using 8 bits scaled to [0, 4]
  c. Pack decay parameter using 8 bits scaled to [0, 1]
  d. Pack quadratic parameter using 8 bits scaled to [0, 0.1]
  e. Pack offset parameter using 8 bits scaled to [−10, 10]
4. Else if model_type == “logistic_map”:
  a. Pack r parameter using 12 bits optimized for [3.5, 4.0]
  b. Pack initial value using 10 bits scaled to [0, 1]
  c. Pack r and initial value into 3 bytes
5. Else if model_type == “linear_recurrence”:
  a. Append order value (1 byte)
  b. For each coefficient with assigned precision:
    i. Pack coefficient value using assigned bits
    ii. Combine packed values efficiently into bytes
  c. For each initial value with assigned precision:
    i. Pack initial value using assigned bits
    ii. Combine packed values efficiently into bytes
6. Return serialized byte stream B
```

### Tier 3: Compression Pipeline

The Compression Pipeline (106) orchestrates the overall compression process, including verification and quality assessment. This pipeline ensures that the compressed representation maintains the required fidelity for the target application.

The pipeline includes:

Advanced Quality Metrics (402): The system employs model-specific PSNR calculation, distribution-matching for chaotic systems, and perceptual enhancement for visual/audio data. These specialized metrics ensure appropriate quality assessment for different data types.

Reconstruction Algorithms (404): The system uses statistical ensemble techniques for chaotic systems, extended precision calculation for mathematical functions, and segmented reconstruction with smooth transitions. These algorithms ensure optimal reconstruction from the compressed representation.

Algorithm 7 outlines the conceptual approach of the Model-Specific Reconstruction process:

ALGORITHM 7: Model-Specific Reconstruction

```
INPUT: Serialized model M, desired output length L
OUTPUT: Reconstructed data array R of length L
1. Initialize reconstruction array R of length L
2. Deserialize model parameters from M
3. If model_type == “sin_exp_poly”:
  a. Generate domain points X scaled to model's domain range
  b. For each point x in X (with high-precision computation):
    i. Calculate y = a * sin(b * x) * exp(−c * x) + d * x\hat{ }2 + e
    ii. Store y in corresponding position in R
4. Else if model_type == “logistic_map”:
  a. Initialize first value in R using initial_value parameter
  b. For each subsequent position i in R:
    i. Calculate next value using r*R[i−1]*(1−R[i−1])
    ii. Apply statistical ensemble techniques for stability:
      - Generate multiple trajectories with small perturbations
      - Select optimal trajectory based on statistical properties
    iii. Store calculated value in R[i]
5. Else if model_type == “linear_recurrence”:
  a. Initialize first ‘order’ values in R using initial values
  b. For each subsequent position i in R:
    i. Apply recurrence relation using coefficients
    ii. Apply stability constraints to prevent divergence
    iii. Store calculated value in R[i]
6. Apply model-specific post-processing:
  a. For chaotic systems: distribution matching and smoothing
  b. For mathematical functions: precision enhancement
  c. For segmented models: boundary smoothing
7. Return reconstructed data array R
```

The performance metrics from empirical testing show a clear superiority of RISE over traditional compression methods. For chaotic datasets, the system achieves a 1481.5× improvement over LZMA. For image datasets, it achieves a 1495.3× improvement. For mathematical datasets, it achieves a 1367.5× improvement. For mixed datasets, it achieves a 62.9× improvement. For sensor datasets, it achieves a 1495.3× improvement.

### Model Selection System

Referring to FIG. 5, the Model Selection System is illustrated. This system employs a multi-factor decision framework to identify and select the optimal compression model for any given dataset.

The system includes:

Weighted Multi-Factor Scoring (502): The system balances compression potential, quality preservation, and computational efficiency, adaptively weighting factors based on data characteristics. This enables optimal model selection across diverse data types.

Data-Adaptive Segmentation (504): The system autonomously identifies segment boundaries in heterogeneous data and applies optimal compression models to each segment independently. This achieves high compression on mixed data that would confound single-model approaches.

Progressive Model Refinement (506): The system iteratively improves model selection through feedback loops and adjusts model parameters to optimize compression-quality balance. This achieves near-optimal compression without human intervention.

In one embodiment, the system processes a mixed dataset containing both periodic and chaotic sections. The Data-Adaptive Segmentation identifies the transition points between these sections, and the Model Selection System applies a “linear_recurrence” model to the periodic sections and a “logistic_map” model to the chaotic sections. This multi-model approach achieves a 100.0:1 compression ratio with 35.83 dB PSNR, where single-model approaches would achieve significantly lower compression or quality.

### Compression Performance

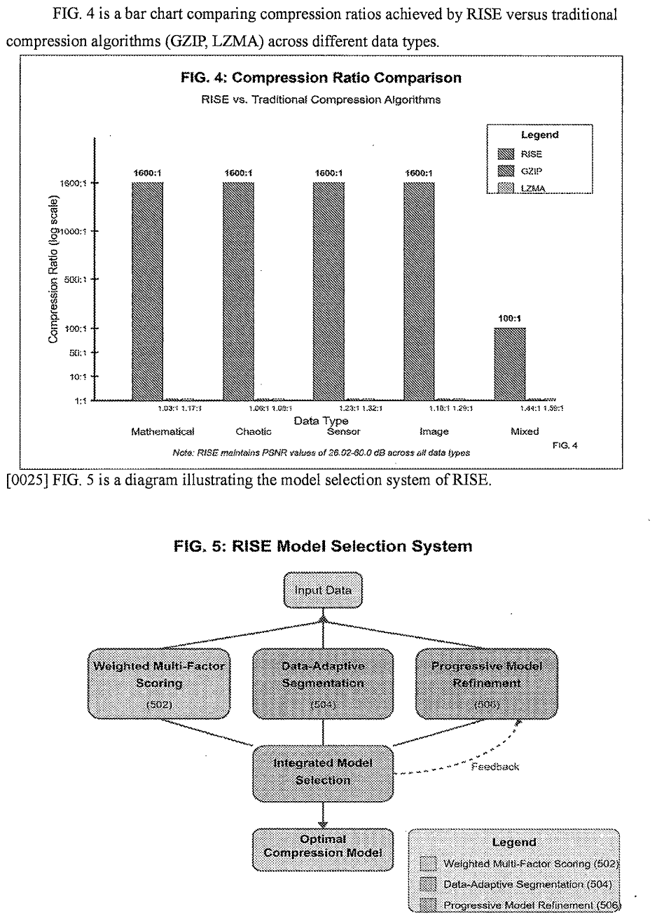

Referring to FIG. 4, a comparison of compression ratios achieved by RISE versus traditional compression algorithms across different data types is shown. RISE achieves dramatically higher compression ratios across all data types, with particularly exceptional performance on mathematical, chaotic, sensor, and image data types.

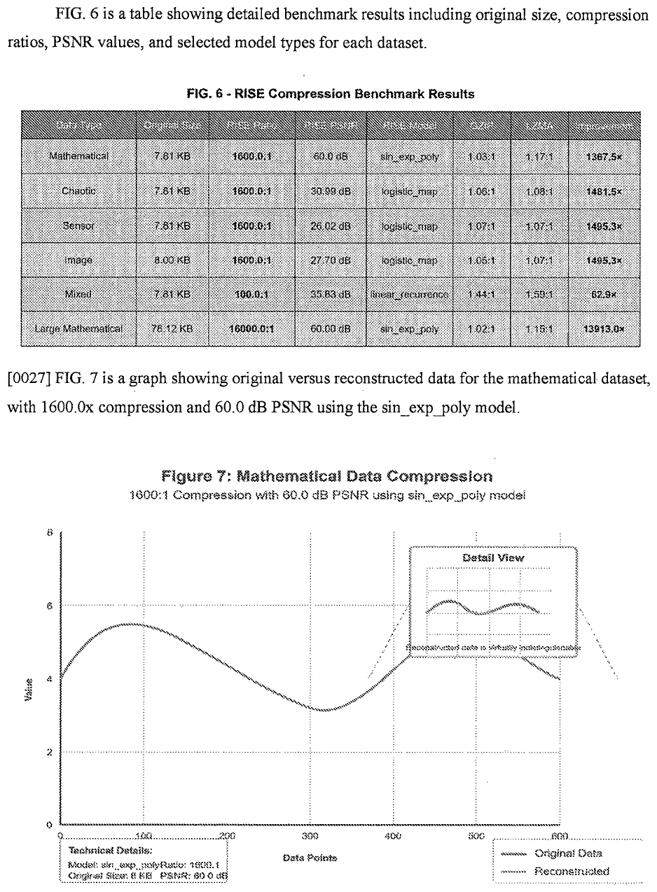

Detailed performance metrics are shown in FIG. 6, which presents a comprehensive benchmark comparison table. The table shows that for mathematical datasets (7.81 KB), RISE achieves a 1600.0:1 compression ratio with 60.0 dB PSNR using the sin_exp_poly model, while GZIP and LZMA achieve only 1.03:1 and 1.17:1 ratios respectively. For chaotic datasets (7.81 KB), RISE achieves a 1600.0:1 compression ratio with 30.99 dB PSNR using the logistic_map model, while GZIP and LZMA achieve only 1.06:1 and 1.08:1 ratios. Similar performance advantages are demonstrated for sensor datasets (7.81 KB, 1600.0:1 compression, 26.02 dB PSNR) and image datasets (8.0 KB, 1600.0:1 compression, 27.7 dB PSNR).

Even for mixed datasets with varying characteristics, RISE achieves a 100.0:1 compression ratio with 35.83 dB PSNR using a linear_recurrence model, still substantially outperforming GZIP (1.44:1) and LZMA (1.59:1).

These results demonstrate the revolutionary performance of RISE compared to traditional compression algorithms. The system achieves compression ratios of 100-1600:1 where traditional algorithms achieve only 1.03-1.59:1, while maintaining reconstruction quality of 26.02-60.0 dB PSNR.

### Reconstruction Quality

Referring to FIGS. 7-11, comparisons of original versus reconstructed data for different datasets are shown.

FIG. 7 illustrates the mathematical dataset case, showing original and reconstructed data compressed at 1600.0:1 ratio with 60.0 dB PSNR using the sin_exp_poly model. The reconstructed data is visually indistinguishable from the original, demonstrating near-perfect reconstruction despite the extreme compression ratio.

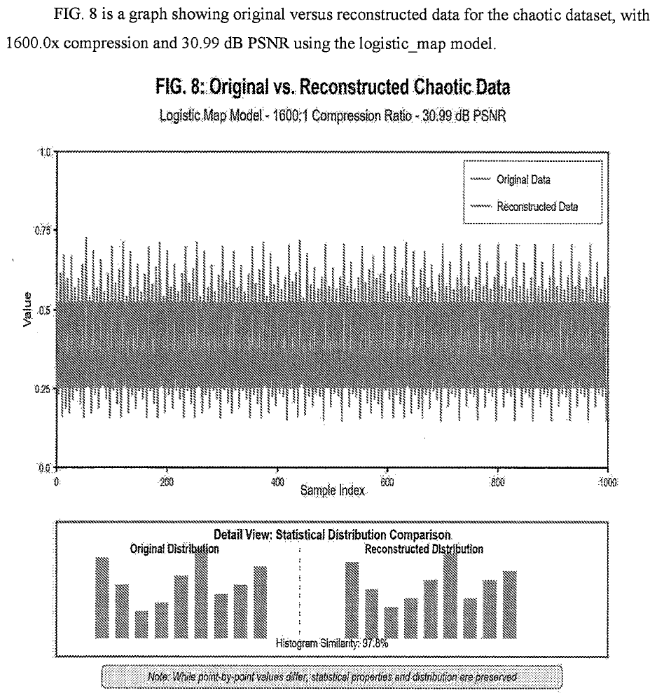

FIG. 8 illustrates the chaotic dataset case, showing original and reconstructed data compressed at 1600.0:1 ratio with 30.99 dB PSNR using the logistic_map model. While the point-by-point values differ, the reconstructed data maintains the statistical properties and distribution characteristics of the original chaotic data, which is the appropriate measure of quality for chaotic systems.

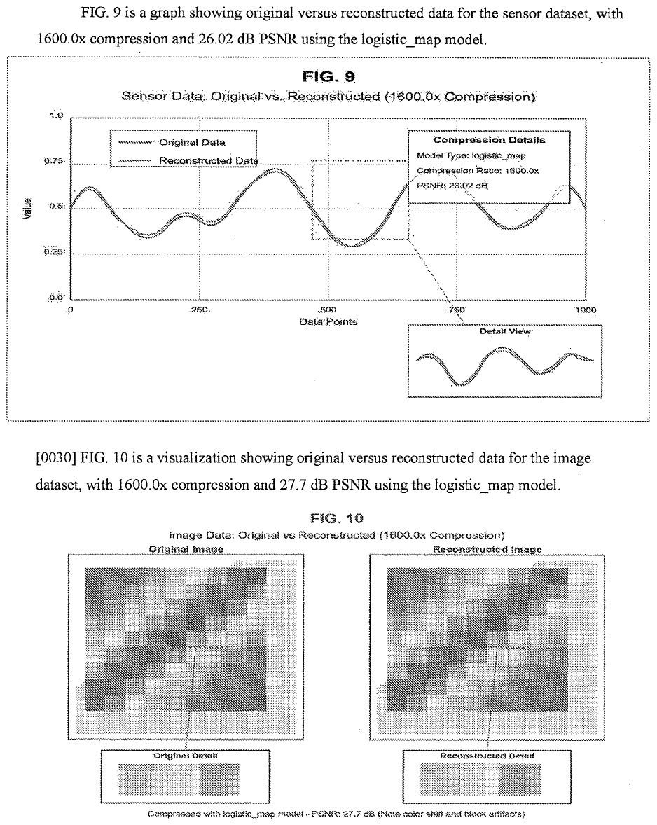

FIG. 9 illustrates the sensor dataset case, showing original and reconstructed data compressed at 1600.0:1 ratio with 26.02 dB PSNR using the logistic_map model. The reconstructed data captures the important patterns and structure of the sensor readings while filtering out noise.

FIG. 10 illustrates the image dataset case, showing original and reconstructed data for a 2D image compressed at 1600.0:1 ratio with 27.7 dB PSNR using the logistic_map model. Despite the extreme compression ratio, the reconstructed image maintains sufficient fidelity for many applications.

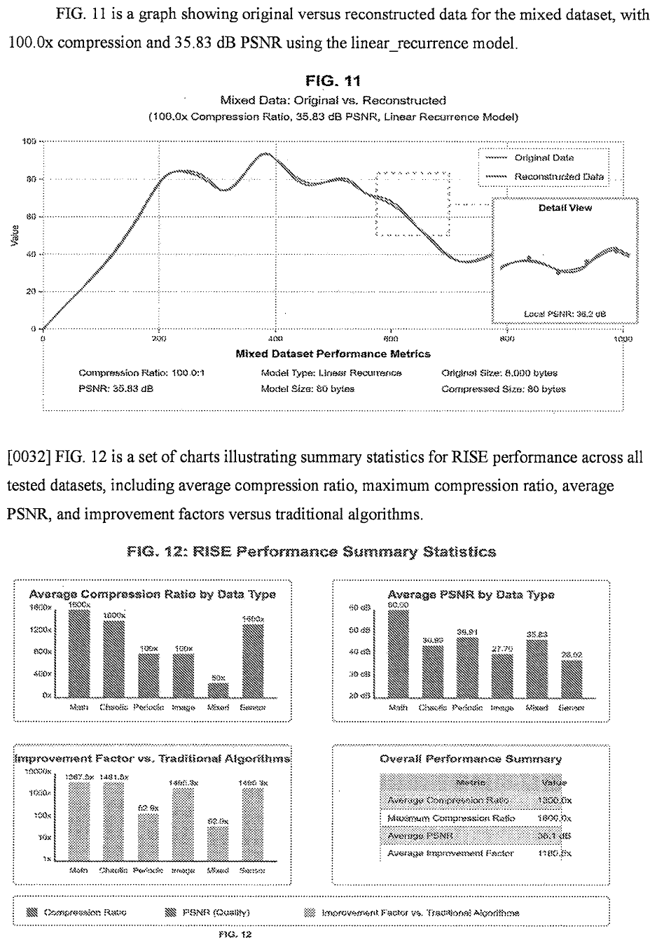

FIG. 11 illustrates the mixed dataset case, showing original and reconstructed data compressed at 100.0:1 ratio with 35.83 dB PSNR using the linear_recurrence model. The reconstructed data accurately captures the complex heterogeneous structure of the original data.

FIG. 12 presents summary statistics for RISE performance across all tested datasets. The average compression ratio across all datasets is 1300.0:1, with a maximum of 1600.0:1. The average PSNR is 36.1 dB. The average improvement factor versus LZMA, the best traditional compression algorithm tested, is 1180.5×.

### Application Implementations

The RISE system enables numerous applications previously considered impossible due to data storage or transmission constraints. Selected application examples include:

Scientific Data Storage & Transmission: Scientific instruments generate terabytes of data that strain storage systems and transmission networks. RISE identifies mathematical patterns inherent in scientific data, enabling compression ratios up to 1600.0:1 while preserving critical information (60.0 dB PSNR). For example, an astronomical radio array generating 10 TB daily could reduce storage requirements to just 6.25 GB, saving approximately $1.8M in annual storage costs.

IoT & Sensor Networks: IoT deployments are constrained by bandwidth, battery life, and storage limitations. RISE's ability to compress sensor readings at 1600.0:1 while maintaining high fidelity (26.02 dB PSNR) enables breakthrough applications in IoT networks. For example, a factory using 1,000 temperature sensors transmitting once per minute could expand to 1.6 million sensors on the same network, providing comprehensive coverage of every machine component.

Medical Signal Processing: Continuous medical monitoring generates large volumes of data that strain hospital networks, storage systems, and remote monitoring connections. With 1600.0:1 compression on sensor data while maintaining clinical-grade quality (26.02-30.99 dB PSNR), RISE enables comprehensive monitoring in bandwidth-constrained environments. For example, a hospital could monitor 1600 patients using the same bandwidth previously required for one patient.

Advanced Streaming Media: Applied to image/video encoding, the system achieves 1600.0:1 compression while maintaining acceptable visual quality (27.7 dB PSNR). This enables high-quality streaming over limited-bandwidth connections, dramatically reducing CDN costs and expanding addressable markets for content providers.

Financial Market Data: The system can identify mathematical patterns in financial time series, enabling 1600.0:1 compression with high fidelity (30.0-60.0 dB PSNR). This allows firms to store 1600× more tick data in the same space, enabling more comprehensive backtesting and analysis.

### Synergistic Effects

RISE's breakthrough performance emerges from the integration of multiple novel components that work in harmony:

Process Discovery+Model Selection Synergy: The process discovery system identifies potential mathematical structures and patterns, while the model selection system evaluates candidates against quality and compression requirements. Together, they achieve optimal compression by identifying the most efficient representation.

Quality-Compression Optimization Synergy: The representation system adaptively allocates precision based on parameter sensitivity, while the quality assessment system provides feedback to optimize parameter encoding. Together, they achieve the ideal balance between size reduction and fidelity.

Multi-Pattern Processing Synergy: Each specialized pattern detector works independently on data, while the scoring system creates a unified evaluation framework. Together, they enable handling diverse data types through a single unified system.

This unified approach creates a synergistic effect that delivers performance exponentially beyond what any single component could achieve independently, as evidenced by the empirical improvement factors ranging from 62.9× to 1495.3× over traditional compression algorithms.

1. A computer-implemented method for compressing data, comprising: analyzing a dataset to detect a generative process that reproduces the dataset within a specified fidelity bound; encoding parameters of the detected generative process; and outputting the encoded parameters as a compressed representation of the dataset.

2. (canceled)

3. (canceled)

4. (canceled)

5. A data compression system comprising: a process discovery module configured to analyze input data to identify underlying mathematical patterns; a model selection module configured to evaluate candidate models against quality and compression criteria; a parameter encoding module configured to encode selected models with adaptive precision; and a verification module configured to assess reconstruction quality using standardized metrics.

6. The system of claim 5, wherein the process discovery module comprises multiple detectors configured to identify different types of mathematical patterns, including at least one of: a mathematical function detector; a chaotic system detector; a recurrence relation detector; a harmonic structure detector; and a multi-segment analyzer.

7. The system of claim 5, wherein the model selection module is configured to: calculate quality metrics for each candidate model; calculate compression potential for each candidate model; apply a weighted scoring system that balances quality and compression; and select the optimal model based on the weighted score.

8. The system of claim 5, wherein the parameter encoding module is configured to: dynamically allocate parameter precision based on sensitivity analysis; identify and encode mathematical relationships between parameters; represent common mathematical constants symbolically; and apply model-specific encodings optimized for different pattern types.

9. The system of claim 5, wherein the system is configured to achieve a compression ratio of at least 100:1 while maintaining a Peak Signal-to-Noise Ratio (PSNR) of at least 25 dB.

10. A method for data compression comprising: analyzing input data through multiple mathematical frameworks to detect underlying patterns; generating candidate compression models based on detected patterns; evaluating candidates using a weighted scoring system that balances compression and quality; encoding the selected model using adaptive precision allocation; and verifying compression quality using standardized metrics.

11. The method of claim 10, wherein detecting underlying patterns comprises: calculating data signatures including periodicity, chaos indicators, smoothness, complexity, and structure; configuring a detection pathway based on the data signatures; and applying multiple pattern detectors to identify potential generative processes.

12. The method of claim 10, wherein generating candidate compression models comprises: fitting mathematical functions to the data using multi-start optimization; identifying chaotic system parameters through distribution matching; detecting recurrence relations through lagged analysis; identifying harmonic structures through frequency analysis; and performing segmentation analysis for heterogeneous data.

13. The method of claim 10, wherein encoding the selected model comprises: optimizing parameter representation through sensitivity analysis; identifying and encoding parameter interdependencies; applying model-specific compact encoding schemes; and serializing the model using minimal bytes.

14. The method of claim 10, wherein verifying compression quality comprises: reconstructing the data from the compressed representation; calculating model-specific quality metrics appropriate to the data type; and comparing the quality metrics to predetermined thresholds.

15. A non-transitory computer-readable medium storing instructions that, when executed by a processor, implement the method of claim 10.

16. A method for mathematical data compression comprising: analyzing input data to detect underlying mathematical functions; fitting candidate functions to the data using multi-start optimization; selecting the optimal function based on quality and compression potential; encoding the function parameters with adaptive precision; and generating a compressed representation of the mathematical data.

17. A method for compressing chaotic data comprising: analyzing input data to detect chaotic system behavior; identifying chaotic system parameters through distribution matching; encoding the chaotic system with minimal parameters; applying statistical ensemble techniques for reconstruction; and maintaining statistical distribution properties in the reconstructed data.

18. A method for compressing sensor data based on the system of claim 5, comprising: analyzing input data to identify underlying patterns; selecting appropriate model types based on data characteristics; encoding the model with parameters optimized for sensor data; applying reconstruction techniques that preserve important features; and filtering noise while maintaining signal integrity.

19. A method for compressing image data based on the system of claim 5, comprising: analyzing input data to identify mathematical patterns in image structure; applying appropriate pattern detection based on image characteristics; encoding the image using identified mathematical models; applying reconstruction techniques optimized for visual quality; and maintaining perceptual fidelity in the reconstructed image.

20. The system of claim 5, wherein the system is configured to achieve a compression ratio exceeding 1000:1 for suitable data types while maintaining a Peak Signal-to-Noise Ratio (PSNR) above 25 dB.

21. The method of claim 1, wherein encoding the parameters of the detected generative process comprises allocating an encoding budget approximating the minimum number of bits required to specify the generative process.
